(19) United States
(12) Patent Application Publication
(10) Pub. No.: US 2024/0266315 A1
(43) Pub. Date: Aug. 8, 2024

(54) SEMICONDUCTOR DEVICE

(71) Applicant: Mitsubishi Electric Corporation, Tokyo (JP)

(72) Inventor: Kazuya OKADA, Tokyo (JP)

(73) Assignee: Mitsubishi Electric Corporation, Tokyo (JP)

(21) Appl. No.: 18/500,993

(22) Filed: Nov. 2, 2023

(30) Foreign Application Priority Data
Feb. 8, 2023 (JP) 2023-017514

(51) Int. Cl. H01L 23/00; H01L 25/07

(52) U.S. Cl. CPC H01L 24/48; H01L 25/072; H01L 2224/48091; H01L 2224/48139; H01L 2924/13091; H01L 2924/30107

(57) ABSTRACT

An object is to provide a technique capable of reducing variations in gate-source voltage among a plurality of semiconductor elements. The semiconductor device includes the plurality of semiconductor elements, a metal electrode, and a control wire. Each of the plurality of semiconductor elements has a control electrode configured to control a main current. The main current of the plurality of semiconductor element flows through the metal electrode. The control wire connects each of the control electrodes of the plurality of semiconductor elements in series, and interlinks with a magnetic field generated when the main current flows through the metal electrode.

### FIELD OF THE INVENTION

The present disclosure relates to a semiconductor device.

### DESCRIPTION OF THE BACKGROUND ART

Typically, when switching on a plurality of semiconductor elements, variations in source potential occur in the plurality of semiconductor elements due to the wiring structure. Such source potential variations cause gate-source voltage variations among a plurality of semiconductor elements, so the main current that flows when switching is on may be concentrated in one of the plurality of semiconductor elements. As a result, there is a problem in that the reliability of the semiconductor device lowers. Therefore, International Publication No. 2018/193929 proposes a technique that generates induced electromotive forces in a gate wire in order to reduce variations in gate-source voltage.

In a conventional technique, variations in gate-source voltage among a plurality of semiconductor devices are reduced by adjusting distances in plan view between the gate wire and the current path generating the magnetic field, thereby regulating the magnitude of the induced electromotive forces generated in the gate wire by the magnetic field. However, for example, there is a problem in the conventional technique in that the variations in gate-source voltage are not reduced when the above-mentioned distances need to be made as equal as possible due to the design of a semiconductor device.

### SUMMARY

The present disclosure has been made in view of the above problem and has an object to provide a technique capable of reducing the variations in gate-source voltage among a plurality of semiconductor elements.

According to the present disclosure, a semiconductor device includes a plurality of semiconductor elements each having a control electrode configured to control a main current, a metal electrode through which the main current of the plurality of semiconductor elements flows, and a control wire connecting each of the control electrodes of the plurality of semiconductor elements in series, and interlinked with a magnetic field generated when the main current flows through the metal electrode.

Variations in gate-source voltage among a plurality of semiconductor elements can be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic top view illustrating a configuration of a semiconductor device according to Embodiment 1;

FIG. 2 is a cross-sectional schematic view illustrating the configuration of the semiconductor device according to Embodiment 1;

FIG. 3 is a cross-sectional schematic view illustrating the configuration of the semiconductor device according to Embodiment 1;

FIG. 4 is a schematic top view illustrating the configuration of the semiconductor device according to Embodiment 1;

FIG. 5 is a schematic diagram illustrating variations in source potential and fluctuation in gate potential of each semiconductor element according to Embodiment 1;

FIG. 6 is a circuit diagram for explaining an induced electromotive force generated in each semiconductor element according to Embodiment 1;

FIG. 7 is a schematic diagram for explaining the induced electromotive force generated in each semiconductor element according to Embodiment 1;

FIG. 8 is a schematic top view illustrating a configuration of a semiconductor device according to Modification;

FIG. 9 is a cross-sectional schematic view illustrating the configuration of the semiconductor device according to Modification;

FIG. 10 is a cross-sectional schematic view illustrating a configuration of a semiconductor device according to Embodiment 2;

FIG. 11 is a cross-sectional schematic view illustrating a configuration of a semiconductor device according to Embodiment 3;

FIG. 12 is a schematic top view illustrating a configuration of a semiconductor device according to Embodiment 4; and

FIG. 13 is a cross-sectional schematic view illustrating a configuration of a semiconductor device according to Embodiment 5.

### DESCRIPTION OF THE PREFERRED EMBODIMENTS

Hereinafter, Embodiments will be described with reference to the attached drawings Features described in each of following Embodiments are examples, and not all features are necessarily essential. In addition, in the description given below, the same or similar components are given the same or similar reference numerals in a plurality of Embodiments, and components that are different will be mainly described. Also, in the following description, terms indicating specific positions or directions such as “up”, “low”, “left”, “right”, “front”, “back” may not necessarily coincide with the positions or directions at the time of implementation.

### Embodiment 1

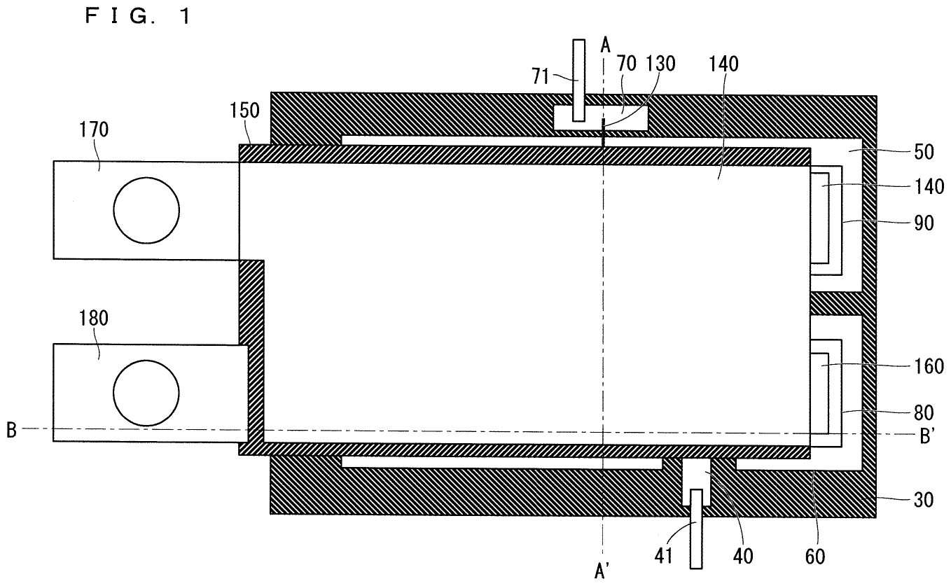

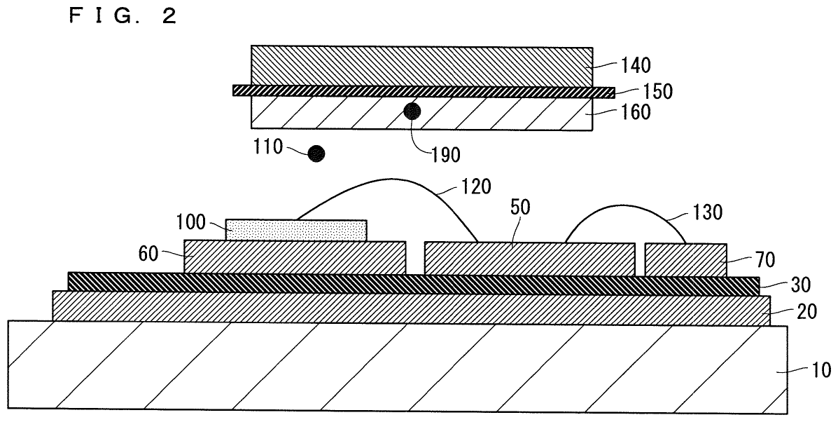

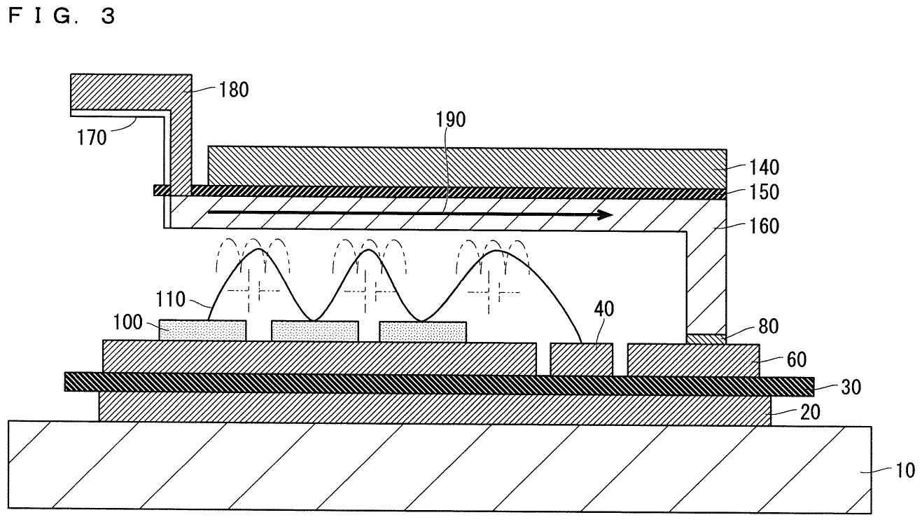

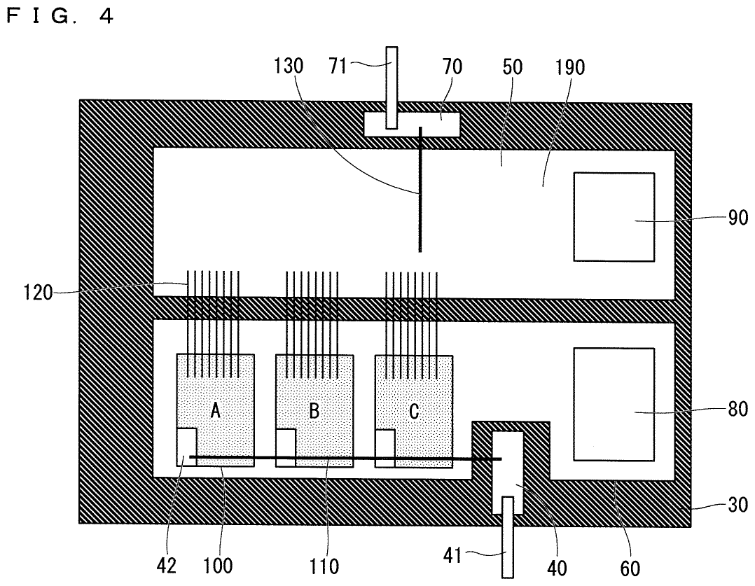

FIG. 1 is a schematic top view illustrating a configuration of a semiconductor device according to Embodiment 1. FIGS. 2 and 3 are cross-sectional schematic view taken along broken lines A-A′ and B-B′ in FIG. 1, respectively. FIG. 4 is a schematic top view illustrating the configuration of FIG. 1 with a part removed.

As illustrated in FIGS. 2 and 3, the semiconductor device according to Embodiment 1 includes a metal base plate 10, an insulating layer 30 provided with a copper pattern, a plurality of semiconductor elements 100, a source metal electrode 140, an electrode insulating layer 150, a drain metal electrode 160 being a metal electrode, a source main terminal 170, and a drain main terminal 180. Further, as illustrated in FIG. 4, the semiconductor device according to Embodiment 1 includes a gate terminal 41, a source control terminal 71, a gate wire 110 being a control wire, a source wire 120, and a source control wire 130.

As illustrated in FIGS. 2 and 3, a back-side copper pattern 20 is provided on the back surface side of the insulating layer 30 (lower side in FIGS. 2 and 3), a gate copper pattern 40, a source copper pattern 50, a drain copper pattern 60, and a source control copper pattern 70 are provided on the front surface side of the insulating layer 30 (upper side in FIGS. 2 and 3). The material of the insulating layer 30 is, for example, ceramics or epoxy resin. The ceramics referred to here includes, for example, at least one of aluminum oxide, aluminum nitride, and silicon nitride. In the present specification, for example, “at least one of A, B, C, . . . , and Z” refers to one of all combinations of one or more extracted from groups of A, B, C, . . . , and Z.

As illustrated in FIGS. 2 and 3, the back-side copper pattern 20 is provided on the metal base plate 10. Although in the examples of FIGS. 2 and 3, the back-side copper pattern 20 is provided between the metal base plate 10 and the insulating layer 30, a resin insulating copper base plate may be adopted in which the metal base plate 10 and the insulating layer 30 are in direct contact with each other without the back-side copper pattern 20, instead of these.

A plurality of semiconductor elements 100 are provided on the drain copper pattern 60 on the opposite side of the back-side copper pattern 20 with regard to the insulating layer 30, and the drain copper pattern 60 is electrically connected to drain electrodes provided under the plurality of semiconductor elements 100. In Embodiment 1, the plurality of semiconductor elements 100 are represented by semiconductor elements A, B, and C, and the number of the plurality of semiconductor elements 100 is not limited to three as long as it is plural. Note that in the following description, when the semiconductor elements A, B, and C are not distinguished, each of the semiconductor elements A, B, and C may be referred to as a semiconductor element 100.

The material of the semiconductor element 100 may be, for example, silicon (Si) or silicon carbide (SiC), which is a wide bandgap semiconductor. That is, the semiconductor element 100 may be a Si semiconductor element or a SiC semiconductor element using these as substrate materials. Also, instead of silicon carbide, a gallium nitride (GaN)-based material, diamond, or the like may be used as the wide bandgap semiconductor. When a wide bandgap semiconductor is used as the material of the semiconductor element 100, the allowable current density can be increased and the power loss can be reduced, therefore, a semiconductor device using the semiconductor element 100 as a power semiconductor element can be miniaturized. The semiconductor element 100 may be, for example, a power control semiconductor element (switching element) such as a Metal Oxide Semiconductor Field Effect Transistor (MOSFET), an Insulated Gate Bipolar Transistor (IGBT) that controls a large current, or may be a combination of a power control semiconductor element and a freewheeling diode. The freewheeling diode may be, for example, a Schottky Barrier Diode (SBD) or a PN junction diode (PND).

As illustrated in FIG. 3, the drain metal electrode 160 has a portion opposite to the plurality of semiconductor elements 100, and the drain copper pattern 60 is connected to the drain metal electrode 160 by a drain metal electrode bonding portion 80. With this, the main current 190 including the drain current and the source current of the plurality of semiconductor elements 100 flows to the drain metal electrode 160. Also, the drain metal electrode 160 is connected to the drain main terminal 180 that is electrically connected to external wiring.

As illustrated in FIG. 4, each of the plurality of semiconductor elements 100 has a gate electrode 42, which is a control electrode for controlling the main current 190, and a source electrode. Note that the source electrode in the example of FIG. 4 is provided on the upper surface of the semiconductor element 100 other than the gate electrode 42, and is insulated from the gate electrode 42. The source electrode of each of the plurality of semiconductor elements 100 is connected to the source copper pattern 50 via the source wire 120.

As illustrated in FIG. 3, the source metal electrode 140 is provided on the drain metal electrode 160 with the electrode insulating layer 150 interposed therebetween, and the source copper pattern 50 of FIG. 1 is connected to the source metal electrode 140 by the source metal electrode bonding portion 90. With this, the main current 190 including the drain current and the source current of the plurality of semiconductor elements 100 flows to the source metal electrode 140. Also, the source metal electrode 140 is connected to the source main terminal 170 that is electrically connected to external wiring.

The drain metal electrode 160 and the source metal electrode 140 are, for example, copper plate electrodes used for inputting and outputting current and voltage. The drain metal electrode 160 and the source metal electrode 140 may be insert-molded or outsert-molded into a case of the semiconductor device (not illustrated). Further, a sealing member (not illustrated) may be provided between the drain metal electrode 160 and the plurality of semiconductor elements 100.

As illustrated in FIG. 4, the source electrode of each of the plurality of semiconductor elements 100 is electrically connected to the source control terminal 71 via the source wire 120, the source copper pattern 50, the source control wire 130, and the source control copper pattern 70.

The gate electrode 42 of each of the plurality of semiconductor elements 100 is connected in series by the gate wire 110, and is electrically connected to the gate terminal 41 via the gate wire 110 and the gate copper pattern 40. For connection between the gate electrodes 42 and the gate wire 110, stitch bonding may be adopted, or bonding other than this may be adopted.

The semiconductor element 100 controls the voltage and the current between the drain electrode and the source electrode based on a voltage value of a gate signal input between the gate terminal 41 and the source control terminal 71. Therefore, according to the semiconductor device configured as described above, the voltage and the current between the drain main terminal 180 and the source main terminal 170 can be controlled by the voltage value of the gate signal input between the gate terminal 41 and the source control terminal 71.

Here, the source control potential of each semiconductor element 100 varies with respect to the source reference potential input from the outside, depending on the position of the semiconductor element 100, the arrangement position of the source wires 120, the path of the main current 190 and the like with respect to the drain copper pattern 60 and the source copper pattern 50. As a result, variations in gate-source voltage occur among the plurality of semiconductor elements 100 and this may cause concentration of the main current 190 in any of the plurality of semiconductor elements 100 are switched on in some cases when the plurality of semiconductor elements 100 are switched on.

In contrast, in Embodiment 1, the gate wire 110 is provided so as to interlink with the magnetic field generated when the main current 190 flows through the drain metal electrode 160. In other words, the positional relationship between the gate wire 110 and the magnetic field generated when the main current 190 flows through the drain metal electrode 160 becomes similar to the positional relationship between the annular portions connected to each other in a typical chain.

For example, when semiconductor elements 100 are turned on in FIG. 3, the main current 190 flows to the source main terminal 170 via the drain main terminal 180, the drain metal electrode 160, the drain metal electrode bonding portion 80, the drain copper pattern 60, the semiconductor elements 100, the source wires 120, the source copper pattern 50, the source metal electrode bonding portion 90, and the source metal electrode 140. The gate wire 110 is provided so as to interlink with the magnetic field that is generated when the main current 190 flows through the drain metal electrode 160. Therefore, when the main current 190 flows through the drain metal electrode 160, the induced electromotive forces are generated on the gate wire 110 by the magnetic field.

As a result, the induced electromotive force is applied to the gate electrode 42, and the gate potential input to each semiconductor element 100 from the outside can be fluctuate. By compensating the gate potential variations for the variations of the source control potential with respect to the source reference potential, that is, the variations in the source potential, as will be described later, variations in gate-source voltage of each semiconductor element 100 can be suppressed.

Note that a magnetic field is also generated when the main current 190 flows through the source metal electrode 140. However, in the configuration where the drain metal electrode 160 is closer to the gate wire 110 than the source metal electrode 140 is as illustrated in FIG. 3, the magnetic field when the main current 190 flows through the drain metal electrode 160 becomes dominant.

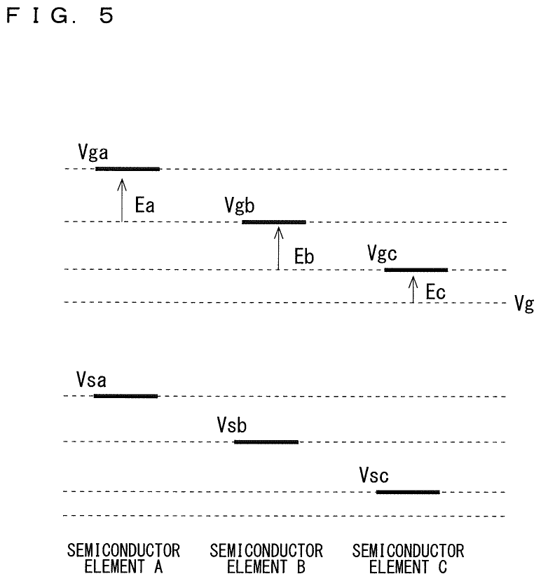

FIG. 5 is a schematic diagram illustrating the variations in source potential and the fluctuations in gate potential of the semiconductor elements A, B, and C. Due to electromagnetic induction caused by di/dt of the main current 190 flowing through the drain metal electrode 160 and the parasitic inductance of the source copper pattern 50, variations occur in the source potentials Vsa, Vsb, and Vsc of the semiconductor elements A, B, and C. In the example of FIG. 4, the connecting portion between the source control wire 130 and the source copper pattern 50 is provided so as to be closest to the semiconductor element C, which is located on the drain metal electrode bonding portion 80 side among the semiconductor elements A, B, and C. In other words, Vsa>Vsb>Vsc is established because the current paths between the connecting portion between the source control wire 130 and the source copper pattern 50 and the semiconductor elements 100 are shorter in the order of the semiconductor element A, the semiconductor element B, and the semiconductor element C.

In a case where the gate wire 110 is provided so as not to interlink with the magnetic field of the main current 190, the gate potential is a constant potential Vg. Therefore, (Vg−Vsc)>(Vg−Vsb)>(Vg−Vsa) is established, in which the variations in gate-source voltage among the plurality of semiconductor elements 100 become relatively large.

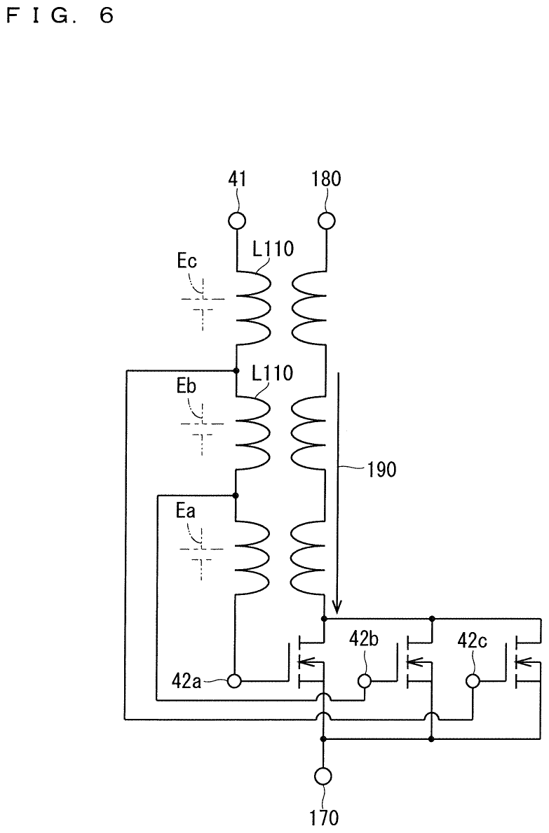

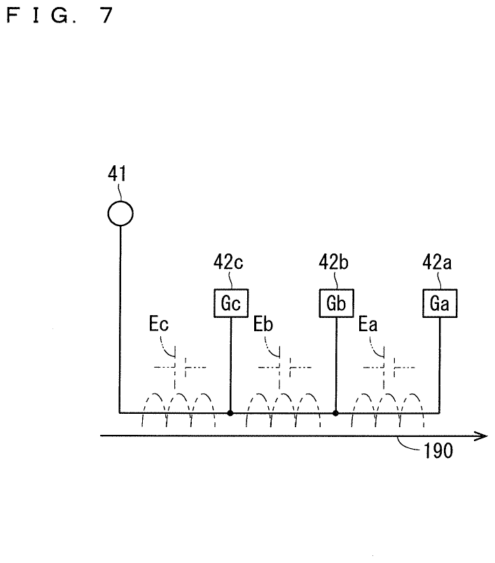

FIGS. 6 and 7 are a circuit diagram and a schematic diagram, respectively, for explaining the induced electromotive force generated in each semiconductor element according to Embodiment 1. As described above, in Embodiment 1, the gate wire 110 is provided so as to interlink with the magnetic field of the main current 190. Therefore, due to electromagnetic induction caused by di/dt of the main current 190 flowing through the drain metal electrode 160 and the parasitic inductance L110 of the gate wire 110, induced electromotive forces Ea, Eb, and Eb are generated in the three bumping portions of the gate wire 110 in FIG. 3, respectively.

In the example of FIG. 4, the gate electrodes 42a, 42b, and 42c of the semiconductor elements A, B, and C are connected in series by the gate wire 110. Further, the gate copper pattern 40 is provided so as to be closest to the semiconductor element C, which is located on the drain metal electrode bonding portion 80 side among the semiconductor elements A, B, and C. The gate electrodes 42a, 42b, and 42c are provided on the opposite side of the drain metal electrode bonding portion 80 with respect to the gate copper pattern 40. Therefore, the induced electromotive force Ec is applied to the gate electrode 42c, the induced electromotive forces Eb and Ec are applied to the gate electrode 42b, and the induced electromotive forces Ea, Eb, and Ec are applied to the gate electrode 42a.

Therefore, as illustrated in FIG. 5, the gate potentials Vga, Vgb, and Vgc of the semiconductor elements A, B, and C can be fluctuated as Vga>Vgb>Vgc in response to the variations in the source potentials Vsa, Vsb, and Vsc. As a result, (Vga−Vsa)≈(Vgb−Vsb)≈(Vgc−Vsc) is established, in which the variations in gate-source voltages among the plurality of semiconductor elements 100 can be suppressed.

### <Summary of Embodiment 1>

According to the semiconductor device of Embodiment 1 as described above, the gate wire 110 connects the respective gate electrodes 42 of the plurality of semiconductor elements 100 in series, and is provided so as to interlink with the magnetic field generated when the main current 190 flows through the drain metal electrode 160. According to such a configuration, variations in gate-source voltage among the plurality of semiconductor elements 100 are suppressed, thereby, consequently, suppressing concentration of the main current 190 in any of the plurality of semiconductor elements 100.

In the conventional technique, the magnitude of the induced electromotive forces generated in the gate wire are adjusted by adjusting the distance in plan view between the gate wire and the current path that generates the magnetic fields of the induced electromotive forces. However, for example, there is a problem in the conventional technique in that the variations in gate-source voltage are not reduced when the above-mentioned distances need to be made as equal as possible due to the design of a semiconductor device.

Whereas, according to Embodiment 1, variations in gate-source voltage can be reduced by adjusting the connecting positions of gate wire 110 and the gate electrodes 42 of the semiconductor elements 100 even if the distances between the plurality of semiconductor elements 100 and the main current 190 are the same in plan view.

### <Modification>

Although the semiconductor device according to Embodiment 1 has been described as a 1 in 1 module with a minimum configuration, the semiconductor device may have an expanded circuit configuration such as a 2 in 1 module or a 6 in 1 module.

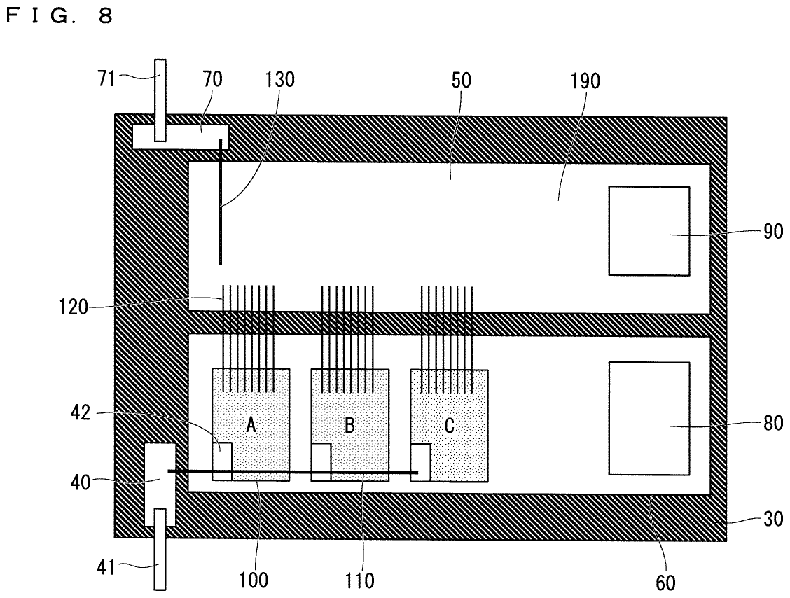

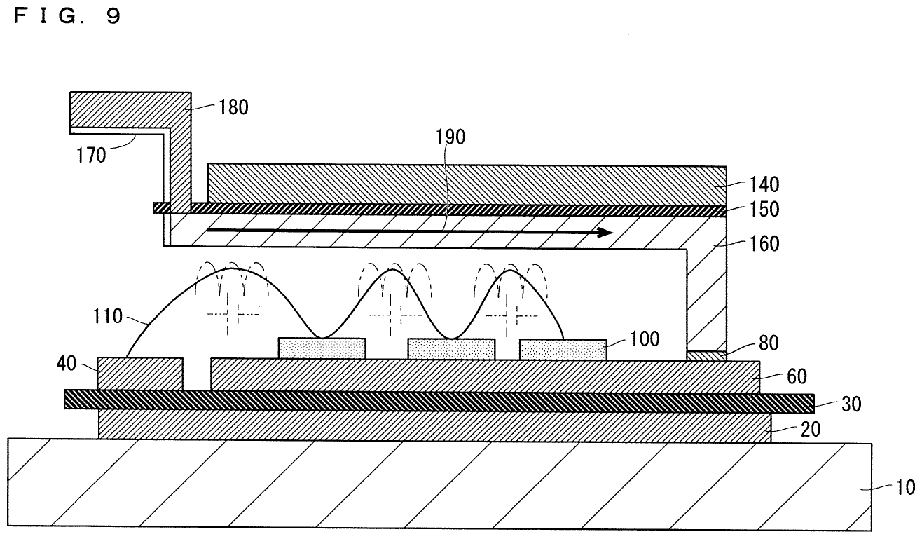

Further, in Embodiment 1, the connecting portion between the source control wire 130 and the source copper pattern 50, and the gate copper pattern 40 are provided so as to be closest to the semiconductor element C, which is located on the drain metal electrode bonding portion 80 side among the semiconductor elements A, B, and C, as illustrated in FIG. 4. Nevertheless, as illustrated in FIGS. 8 and 9, the connecting portion between the source control wire 130 and the source copper pattern 50, and the gate copper pattern 40 may be provided so as to be closest to the semiconductor element A, which is located on the opposite side of the drain metal electrode bonding portion 80 among the semiconductor elements A, B, and C. And the gate electrodes 42a, 42b, and 42c may be provided on the drain metal electrode bonding portion 80 side with respect to the gate copper pattern 40. With such a configuration as well, the same effects as those in Embodiment 1 can be obtained.

Further, in Embodiment 1, the drain metal electrode 160 is closer to the gate wire 110 than the source metal electrode 140 is, however, the source metal electrode 140 may be closer to the gate wire 110 than the drain metal electrode 160. In this case, the gate wire 110 may be provided so as to interlink with the magnetic field generated when the main current 190 flows through the source metal electrode 140. However, since the direction of the induced electromotive forces are determined by the direction of the main current 190, the position of the connecting portion of the source control wire 130 and the source copper pattern 50 and the position of the gate copper pattern 40 are changed as appropriate considering the direction in which the main current 190 flows through the source metal electrode 140.

### Embodiment 2

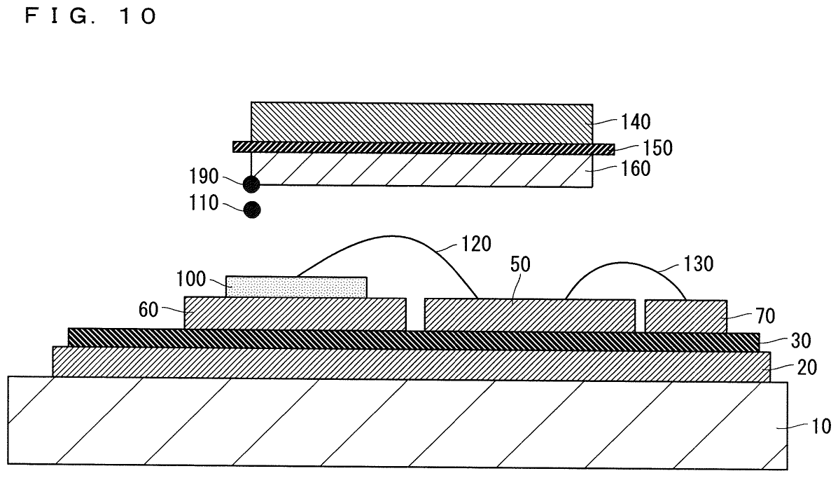

FIG. 10 is a cross-sectional perspective view illustrating a configuration of a semiconductor device according to Embodiment 2, which corresponds to FIG. 2.

In FIG. 2, the main current 190 is illustrated flowing through the center of the drain metal electrode 160 when viewed from the direction in which the main current 190 flows in the drain metal electrode 160. However, the main current 190 concentrates at the end portion of the drain metal electrode 160 as the switching frequency becomes higher.

In response to this, in Embodiment 2, the gate wire 110 is provided in the vicinity of the end portion of the drain metal electrode 160 when viewed from the direction in which the main current 190 flows in the drain metal electrode 160. For example, the gate wire 110 may be provided closer to the end portion of the drain metal electrode 160 than to the center, or may be provided closer to the end portion of the drain metal electrode 160 than to any portion other than the end portion.

According to the semiconductor device of Embodiment 2 as described above, the gate wire 110 and the main current 190 in the drain metal electrode 160 can be brought close to each other; therefore, the induced electromotive forces generated in the gate wire 110 can be increased.

### Embodiment 3

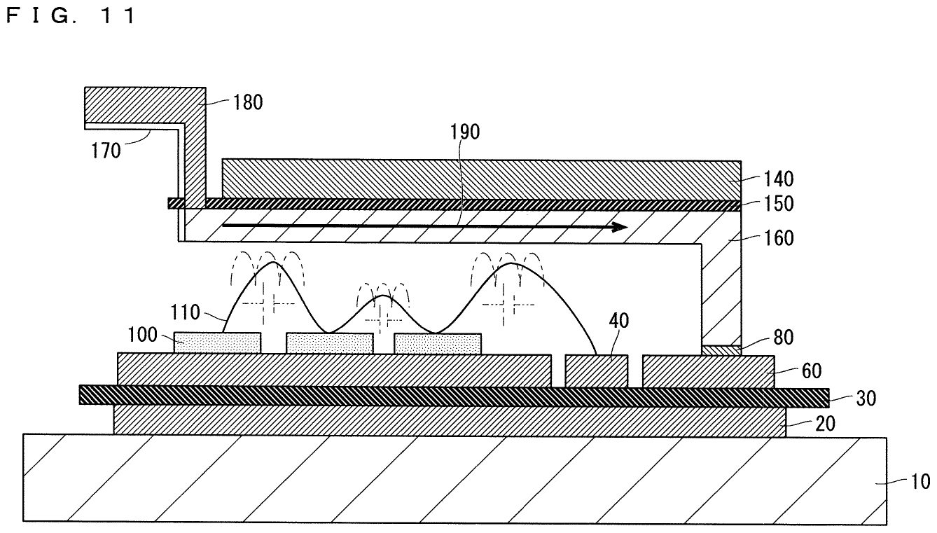

FIG. 11 is a cross-sectional perspective view illustrating a configuration of a semiconductor device according to Embodiment 3, which corresponds to FIG. 3.

In Embodiment 3, based on the induced electromotive force that is to be cumulatively applied to the gate electrode 42 of the semiconductor element 100 by the magnetic field, a distance between a portion of the gate wire 110 corresponding to the induced electromotive force and the drain metal electrode 160 is set.

In the example of FIG. 11, a distance between a portion of the gate wire 110 corresponding to the induced electromotive force Ea and the drain metal electrode 160 is made relatively small in order to increase the induced electromotive force Ea that is to be cumulatively applied to the gate electrode 42a of the semiconductor element A. In addition, a distance between a portion of the gate wire 110 corresponding to the induced electromotive force Eb and the drain metal electrode 160 is made relatively large in order to reduce the induced electromotive force Eb that is to be cumulatively applied to the gate electrode 42b of the semiconductor element B.

According to the semiconductor device of Embodiment 3, the gate-source voltage in the semiconductor elements 100 can be adjusted; therefore, variations in gate-source voltage among the plurality of semiconductor elements 100 are suppressed.

### Embodiment 4

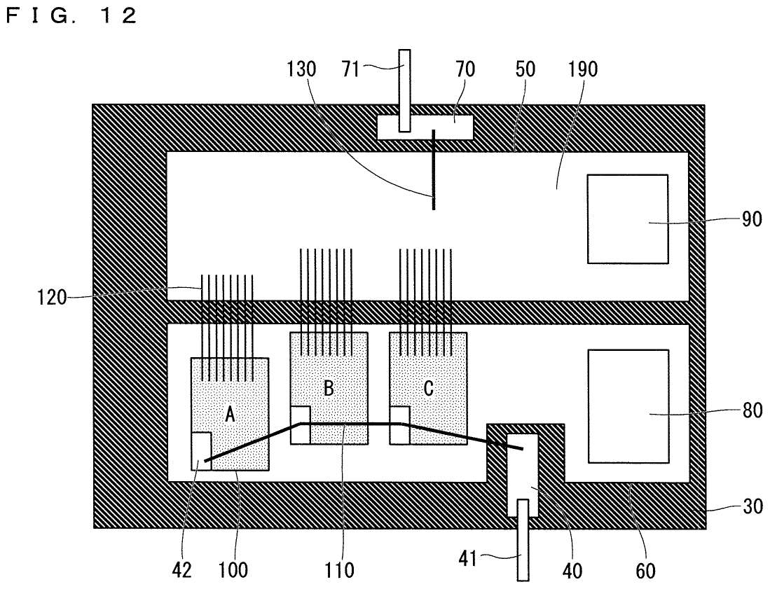

FIG. 12 is a schematic top view illustrating a configuration of a semiconductor device according to Embodiment 4, which corresponds to FIG. 4.

In Embodiment 4, based on the induced electromotive forces that are to be cumulatively applied to the gate electrodes 42 of the semiconductor elements 100 by the magnetic field, angles between the extending direction of portions of the gate wire 110 corresponding to the induced electromotive forces and the direction of the main current 190 in the drain metal electrode 160 in plan view are set.

In the example of FIG. 12, an angle between the extending direction of a portion of the gate wire 110 corresponding to the induced electromotive force Ea and the direction of the main current 190 in plan view is relatively large in order to reduce the induced electromotive force Ea that is to be cumulatively applied to the gate electrode 42a of the semiconductor element A. Note that the portion of the gate wire 110 corresponding to the induced electromotive force Ea is a portion between the semiconductor element A and the semiconductor element B. In addition, an angle between the extending direction of a portion of the gate wire 110 corresponding to the induced electromotive force Eb and the direction of the main current 190 in plan view is relatively small in order to increase the induced electromotive force Eb that is to be cumulatively applied to the gate electrode 42b of the semiconductor element B. Note that the portion of the gate wire 110 corresponding to the induced electromotive force Eb is a portion between the semiconductor element B and the semiconductor element C.

According to the semiconductor device of Embodiment 4, the gate-source voltage in the semiconductor elements 100 can be adjusted; therefore, variations in gate-source voltage among the plurality of semiconductor elements 100 are suppressed.

### Embodiment 5

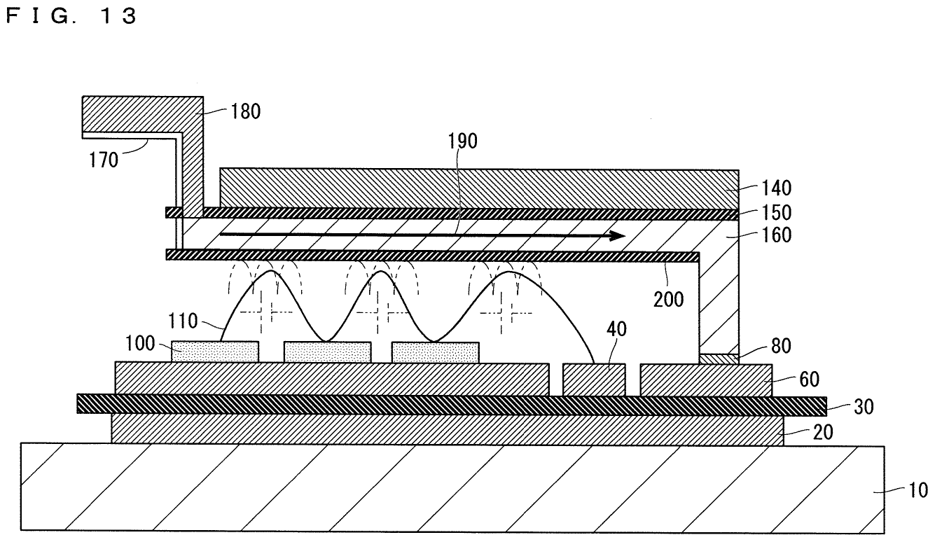

FIG. 13 is a cross-sectional perspective view illustrating a configuration of a semiconductor device according to Embodiment 5, which corresponds to FIG. 3.

The configuration in FIG. 13 is similar to a configuration in which an electrode element side insulating layer 200 being an insulating layer is added to the configuration of FIG. 3. The electrode element side insulating layer 200 is provided on the surface of the drain metal electrode 160 on the gate wire 110 side.

According to the semiconductor device of Embodiment 5, the high portions of the gate wire 110 can be provided in the vicinity of the electrode element side insulating layer 200 or in contact with the electrode element side insulating layer 200. This allows the gate wire 110 and the main current 190 in the drain metal electrode 160 to be brought close to each other, so that the induced electromotive forces generated in the gate wire 110 can be increased.

It should be noted that Embodiments and Modifications can be arbitrarily combined and can be appropriately modified or omitted.

Hereinafter, the aspects of the present disclosure will be collectively described as Appendices.

### APPENDIX 1

A semiconductor device comprising:
a plurality of semiconductor elements each having a control electrode configured to control a main current;
a metal electrode through which the main current of the plurality of semiconductor elements flows; and
a control wire connecting each of the control electrodes of the plurality of semiconductor elements in series, and interlinked with a magnetic field generated when the main current flows through the metal electrode.

### APPENDIX 2

The semiconductor device according to Appendix 1, wherein
the control wire is provided in the vicinity of an end portion of the metal electrode when viewed from a direction in which the main current flows in the metal electrode.

### APPENDIX 3

The semiconductor device according to Appendix 1 or 2, wherein
based on induced electromotive forces that are to be cumulatively applied to the control electrodes of the semiconductor elements by the magnetic field, distances between portions of the control wire corresponding to the induced electromotive forces and the metal electrode are set.

### APPENDIX 4

The semiconductor device according to any one of Appendices 1 to 3, wherein
based on the induced electromotive forces that are to be cumulatively applied to the control electrodes of the semiconductor elements by the magnetic field, angles between the extending direction of portions of the control wire corresponding to the induced electromotive forces and a direction of the main current in the metal electrode in plan view are set.

### APPENDIX 5

The semiconductor device according to any one of Appendices 1 to 4, further comprising
an insulating layer provided on a surface of the metal electrode on the control wire side.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a plurality of semiconductor elements each having a control electrode configured to control a main current;
a metal electrode through which the main current of the plurality of semiconductor elements flows; and
a control wire connecting each of the control electrodes of the plurality of semiconductor elements in series, and interlinked with a magnetic field generated when the main current flows through the metal electrode.

2. The semiconductor device according to claim 1, wherein
the control wire is provided in the vicinity of an end portion of the metal electrode when viewed from a direction in which the main current flows in the metal electrode.

3. The semiconductor device according to claim 1, wherein
based on induced electromotive forces that are to be cumulatively applied to the control electrodes of the semiconductor elements by the magnetic field, distances between portions of the control wire corresponding to the induced electromotive forces and the metal electrode are set.

4. The semiconductor device according to claim 1, wherein
based on the induced electromotive forces that are to be cumulatively applied to the control electrodes of the semiconductor elements by the magnetic field, angles between the extending direction of portions of the control wire corresponding to the induced electromotive forces and a direction of the main current in the metal electrode in plan view are set.

5. The semiconductor device according to claim 1, further comprising
an insulating layer provided on a surface of the metal electrode on the control wire side.

6. The semiconductor device according to claim 2, wherein
based on induced electromotive forces that are to be cumulatively applied to the control electrodes of the semiconductor elements by the magnetic field, distances between portions of the control wire corresponding to the induced electromotive forces and the metal electrode are set.

7. The semiconductor device according to claim 2, wherein
based on the induced electromotive forces that are to be cumulatively applied to the control electrodes of the semiconductor elements by the magnetic field, angles between the extending direction of portions of the control wire corresponding to the induced electromotive forces and a direction of the main current in the metal electrode in plan view are set.

8. The semiconductor device according to claim 2, further comprising
an insulating layer provided on a surface of the metal electrode on the control wire side.
